(19) United States
(12) Patent Application Publication
(10) Pub. No.: US 2026/0247937 A1
(43) Pub. Date: Aug. 20, 2026

(54) SAFETY ASSISTANCE DEVICE, INFERENCE DEVICE, MACHINE LEARNING DEVICE, SAFETY ASSISTANCE METHOD, INFERENCE METHOD, AND MACHINE LEARNING METHOD

(71) Applicant: EBARA CORPORATION, Tokyo (JP)

(72) Inventor: Seiji MURATA, Tokyo (JP)

(21) Appl. No.: 19/133,548

(22) PCT Filed: Oct. 17, 2023
(86) PCT No.: PCT/JP2023/037506

§ 371 Date: May 28, 2025

(30) Foreign Application Priority Data
Nov. 28, 2022 (JP) 2022-189586

(51) Int. Cl. H10P 95/00; G06T 7/70; H10P 52/00

(52) U.S. Cl. CPC H10P 95/00; G06T 7/70; H10P 52/00

(57) ABSTRACT

[Problem] To provide a safety support device capable of improving the work efficiency of the operator while appropriately ensuring the safety of the operator.
[Solution]

A safety support device 5 supports the safety of an operator U who performs a predetermined task by placing at least a part of their body into a predetermined movable range with respect to a processing device that performs predetermined processing by moving a movable part having the predetermined movable range. The safety support device 5 includes: an image data acquisition unit 500 that acquires image data 110 captured by an image capturing unit 63 disposed in front of the operator U when an operator device 6 is worn by the operator U; and an interlock information generation unit 501 that generates interlock information indicating an interlock state of the movable part based on the image data 110 acquired by the image data acquisition unit 500.

### TECHNICAL FIELD

The present invention relates to a safety support device, an inference device, a machine learning device, a safety support method, an inference method, and a machine learning method.

### BACKGROUND ART

In substrate processing devices that perform various processes on substrates such as semiconductor wafers, for example, an interlock function is provided for a movable part having a predetermined movable range in order to ensure the safety of the operator. For example, PTL 1 discloses a substrate processing device in which, when the open state of a cover provided on each module (movable part) of the substrate processing device is detected by a sensor, an interlock is activated to stop that module.

### CITATION LIST

### Patent Literature

PTL 1 JP 2013-077053 A

### SUMMARY OF INVENTION

### Technical Problem

In various processing devices including the substrate processing device disclosed in PTL 1, various operations are performed by operators, and such operations are performed with a part of the operator's body inside the movable range of a movable part. Accordingly, an interlock function as described above is necessary for the processing device, however, for example, during adjustment or maintenance operations, temporarily disabling the interlock function can improve work efficiency. Nevertheless, if the interlock function is temporarily disabled, the safety of the operator is not ensured by the processing device, presenting a problem in terms of operator safety.

In view of the above-described problem, it is an object of the present invention to provide a safety support device, an inference device, a machine learning device, a safety support method, an inference method, and a machine learning method capable of improving the work efficiency of the operator while appropriately ensuring the safety of the operator.

### Solution to Problem

In order to achieve the above-described object, a safety support device according to one aspect of the present invention is a safety support device that supports the safety of an operator who performs a predetermined task by placing at least a part of their body into a predetermined movable range with respect to a processing device that performs predetermined processing by moving a movable part having the predetermined movable range, the safety support device including: an image data acquisition unit that acquires image data captured by an image capturing unit disposed in front of the operator when an operator device including the image capturing unit is worn by the operator; and an interlock information generation unit that generates interlock information indicating an interlock state of the movable part based on the image data acquired by the image data acquisition unit.

### Effects of the Invention

According to one aspect of the safety support device of the present invention, since interlock information indicating the interlock state of the movable part is generated based on image data captured by an image capturing unit disposed in front of the operator, the interlock of the movable part can be controlled according to the positional relationship between the operator and the movable part. Therefore, it is possible to improve the work efficiency of the operator while appropriately ensuring the safety of the operator.

Other objects, configurations, and effects will be clarified in the embodiments for implementing the invention described below.

### BRIEF DESCRIPTION OF DRAWINGS

FIG. 1 is an overall configuration diagram showing an example of a substrate processing system 1.

FIG. 2 is a plan view showing an example of a substrate processing device 2.

FIG. 3 is a perspective view showing an example of first to fourth polishing units 22A to 22D.

FIG. 4 is a perspective view showing an example of first and second roll sponge cleaning units 24A and 24B.

FIG. 5 is a perspective view showing an example of first and second pen sponge cleaning units 24C and 24D.

FIG. 6 is a perspective view showing an example of first and second drying units 24E and 24F.

FIG. 7 is a block diagram showing an example of the substrate processing device 2.

FIG. 8 is a hardware configuration diagram showing an example of a computer 900.

FIG. 9 is a block diagram showing an example of a machine learning device 4.

FIG. 10 is a diagram showing an example of a learning model 10 and training data 11.

FIG. 11 is a flowchart showing an example of a machine learning method performed by the machine learning device 4.

FIG. 12 is a block diagram showing an example of a safety support device 5.

FIG. 13 is a functional explanatory diagram showing an example of the safety support device 5.

FIG. 14 is a block diagram showing an example of a user terminal device 6.

FIG. 15 is a flowchart showing an example of a safety support method performed by the substrate processing device 2, the safety support device 5, and the user terminal device 6.

FIG. 16 is a diagram showing a first example in which interlock information 111A is superimposed on a movable part in the real space.

FIG. 17 is a diagram showing a second example in which interlock information 111B is superimposed on a movable part in the real space.

### DESCRIPTION OF EMBODIMENTS

Hereinafter, an embodiment for implementing the present invention will be described with reference to the drawings. The following provides a schematic illustration of the scope necessary for explaining the objectives of the present invention. The description will primarily focus on the relevant portions of the invention, and any parts not explicitly explained will be assumed to be based on known technologies.

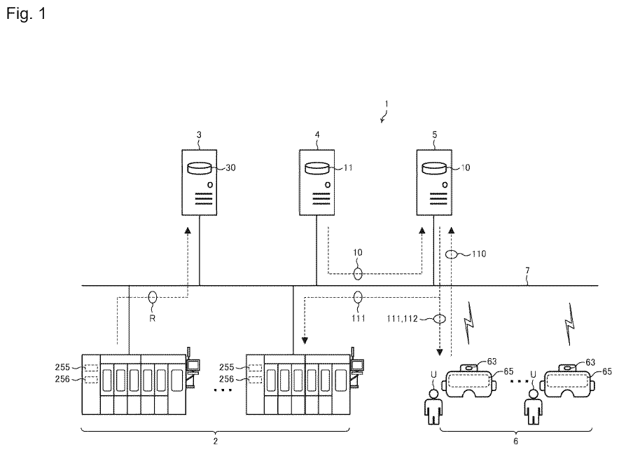

FIG. 1 is an overall configuration diagram showing an example of a substrate processing system 1. The substrate processing system 1 according to the present embodiment functions as a system that manages a series of substrate processing tasks including a chemical mechanical polishing process (hereinafter referred to as a “polishing process”) for polishing the surface of a substrate (hereinafter referred to as a “wafer”) W such as a semiconductor wafer to a flat surface by pressing the wafer W against a polishing pad supplied with a polishing fluid, a cleaning process for cleaning the surface of the wafer W after polishing by supplying a cleaning fluid while bringing it into contact with a cleaning tool, and a drying process for drying the surface of the wafer W after cleaning.

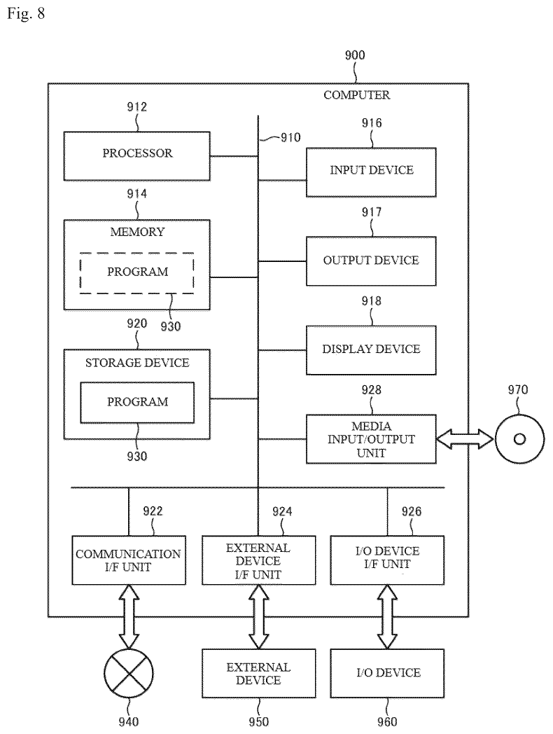

The substrate processing system 1 mainly includes a substrate processing device 2, a database device 3, a machine learning device 4, a safety support device 5, and a user terminal device 6. Each of the devices 2 to 6 is, for example, a general-purpose or dedicated computer (see FIG. 8 described later), and is connected to a wired or wireless network 7 so that various types of data can be exchanged between them (in FIG. 1, transmission and reception of some of the data are depicted using dashed arrows). The number of devices 2 to 6 and the connection configuration of the network 7 are not limited to the example in FIG. 1, and may be changed as appropriate.

The substrate processing device 2 is composed of a plurality of units, each provided with a movable part having a predetermined movable range, and performs a series of substrate processing operations such as loading, polishing, cleaning, drying, and unloading on one or more wafers W. In doing so, the substrate processing device 2 operates each unit by moving the corresponding movable parts while referring to device setting information 265 consisting of a plurality of device parameters set for each unit, and substrate recipe information 266 that defines the operating conditions for the polishing, cleaning, and drying processes.

The movable parts are configured to be capable of linear or rotational movement using, for example, electric power or fluid pressure as a drive source, When a predetermined interlock condition is satisfied, interlock control that restricts the movement of the movable part is performed by the substrate processing device 2. The interlock condition is deemed satisfied, for example, when an interlock state of a movable part is detected by various interlock sensors provided in the substrate processing device 2, or when interlock information 111 indicating the interlock state of a movable part is received from the safety support device 5. The interlock control may either restrict the movement of the movable part without cutting off the drive source and release the restriction on the movement when the interlock condition is cleared, or may restrict the movement of the movable part by cutting off the drive source and only release the restriction on the movement when both the interlock condition is cleared and an operation to cancel the cutoff of the drive source is performed.

In accordance with the movement of each movable part under interlock control, the substrate processing device 2 transmits various reports R to the database device 3, the user terminal device 6, and the like. The various reports R may include, for example process information identifying the wafer W subjected to substrate processing, device state information indicating the state of each unit at the time of each process, event information detected by the substrate processing device 2, and operation information of the operator U with respect to the substrate processing device 2.

The database device 3 manages production history information 30 related to the history of substrate processing performed using production wafers W, processing components, and processing fluids. The database device 3 receives various reports R from the substrate processing device 2 as needed when substrate processing is performed by the substrate processing device 2, and registers them in the production history information 30, thereby accumulating the reports R related to substrate processing in the production history information 30. Additionally, the database device 3 may also store the device setting information 255 and substrate recipe information 256, in which case the substrate processing device 2 may refer to such information.

The machine learning device 4 is a device that operates as the main entity during the training phase of machine learning. Based on a plurality of sets of training data 11 for example, the machine learning device 4 generates, through machine learning, a learning model 10 used by the safety support device 5. The trained learning model 10 is provided to the safety support device 5 via the network 7 or a recording medium.

The safety support device 5 is a device that operates as the main entity during the inference phase of machine learning, and supports the safety of the operator U when the operator U performs predetermined tasks by placing at least a part of their body into the movable range of a movable part of the substrate processing device 2. Tasks performed by the operator U may include various tasks such as for example, replacing consumable components used in the substrate processing device 2, adjusting the device setting information 265, recovering from malfunctions occurring in the substrate processing device 2, and performing maintenance work (including preventive maintenance) of the substrate processing device 2.

The safety support device 5 receives, as needed, image data 110 (details to be described later) from the user terminal device 6 worn by the operator U performing tasks on the substrate processing device 2. By inputting the image data 110 into the learning model 10 provided by the machine learning device 4, the safety support device 5 generates interlock information 111 indicating the interlock state of the movable parts while the operator U is performing work on the substrate processing device 2, and transmits the interlock information 111 as needed to the substrate processing device 2, the user terminal device 6, and the like.

The user terminal device 6 is an operator device used when the operator U performs work on the substrate processing device 2. The user terminal device 6 is a portable device that can be worn on the head or the like by the operator U, and is constituted by wearable devices such as smart glasses, a transmissive head-mounted display, or the like. The user terminal device 6 includes an image capturing unit 63 capable of capturing the real space, and an output unit 65 capable of superimposing and displaying object information 112 on objects in the real space. Other specific configurations will be described later.

The image capturing unit 63 is constituted by a camera (image sensor) such as a CMOS sensor or a CCD sensor having a predetermined resolution (number of pixels), and is disposed in front of the operator U when the operator U wears the user terminal device 6. When the operator U performs work on the substrate processing device 2, the user terminal device 6 transmits the image data 110 captured by the image capturing unit 63, which is disposed in front of the operator U, to the safety support device 5 as needed. The output unit 65 is disposed, for example, in front of one or both eyes of the operator U when the user terminal device 6 is worn by the operator V. The user terminal device 6 receives, as needed, interlock information 111 or object information 112 for the image data 110 from the safety support device 5, and displays the interlock information 111 or object information 112 so as to be superimposed on objects present in the real space within the field of view of the operator U, for example.

### Substrate Processing Device 2

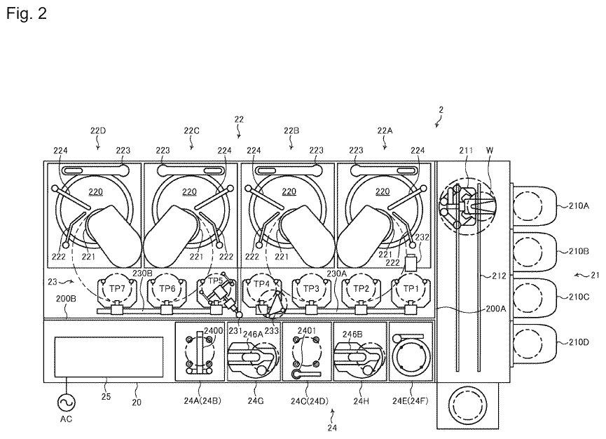

FIG. 2 is a plan view showing an example of the substrate processing device 2. The substrate processing device 2 includes, within a substantially rectangular housing 20 in plan view, a load/unload unit 21, a polishing unit 22, a substrate transport unit 23, a finishing unit 24, and a control unit 25. The load/unload unit 21 is partitioned from the polishing unit 22, the substrate transport unit 23, and the finishing unit 24 by a first partition wall 200A, and the substrate transport unit 23 and the finishing unit 24 are partitioned by a second partition wall 200B. A cover or door (neither shown) that is openable/closable or detachable is attached to a side wall portion of the housing 20 so that at least a part of the body of the operator U can enter the interior during work.

### Load/Unload Unit

The load/unload unit 21 includes first to fourth front load units 210A to 210D on which wafer cassettes (FOUPs and the like) capable of storing a plurality of wafers W in the vertical direction are placed, a transport robot 211 that can move up and down along the storage direction (vertical direction) of the wafers W stored in the wafer cassettes, and a horizontal movement mechanism 212 that moves the transport robot 211 along the arrangement direction of the first to fourth front load units 210A to 210D (short side direction of the housing 20).

The transport robot 211 is configured to be accessible to the wafer cassettes placed on each of the first to fourth front load units 210A to 210D, the substrate transport unit 23 (specifically, a lifter 232 to be described later), and the finishing unit 24 (specifically, first and second drying units 24E and 24F to be described later), and is provided with upper and lower two-stage hands (not shown) for delivering wafers W between them. The lower hand is used for delivering unprocessed wafers W, and the upper hand is used for delivering processed wafers W. During the delivery of wafers W to and from the substrate transport unit 23 or the finishing unit 24, a shutter (not shown) provided in the first partition wall 200A is opened and closed.

Note that in FIG. 2, the specific configurations of the transport robot 211 and the horizontal movement mechanism 212, which respectively function as movable parts, are omitted. However, for example, they may be configured by appropriately combining AC devices such as servo motors, power transmission mechanisms such as linear guides, ball screws, gears, belts, couplings, and bearings, output devices such as fluid pressure cylinders and valves, and input devices such as linear sensors, encoder sensors, limit sensors, and torque sensors.

### Polishing Unit

The polishing unit 22 includes first to fourth polishing units 22A to 22D, each of which performs polishing processing (planarization) of a wafer W. The first to fourth polishing units 22A to 22D are arranged in a line along the longitudinal direction of the housing 20.

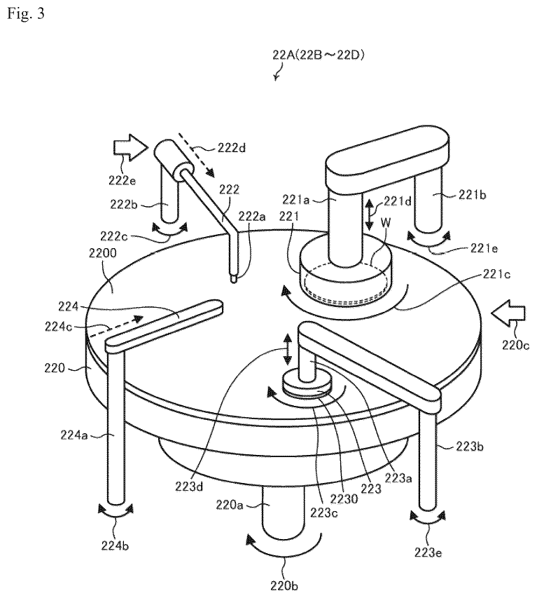

FIG. 3 is a perspective view showing an example of the first to fourth polishing units 22A to 22D. The basic configurations and functions of the first to fourth polishing units 22A to 22D are the same.

Each of the first to fourth polishing units 22A to 22D includes a polishing table (processing member support unit) 220 that rotatably supports a polishing pad 2200 having a polishing surface, a top ring (substrate holding unit) 221 that rotatably holds the wafer W and polishes the wafer W while pressing it against the polishing pad 2200 on the polishing table 220, a polishing fluid supply unit 222 that supplies polishing fluid to the polishing pad 2200, a dresser 223 that rotatably supports a dresser disk 2230 and brings a dresser disk 2230 into contact with the polishing surface of the polishing pad 2200 to dress the polishing pad 2200, and an atomizer 224 that sprays pad cleaning fluid onto the polishing pad 2200.

The polishing table 220 includes a rotational movement mechanism 220b that is supported by a polishing table shaft 220a to rotationally drive the polishing table 220 about its axis and a temperature control mechanism 220c that adjusts the surface temperature of the polishing pad 2200.

The top ring 221 includes a rotational movement mechanism 221c that is supported by a top ring shaft 221a that is movable in the vertical direction to rotationally drive the top ring 221 about its axis, a vertical movement mechanism 221d that moves the top ring 221 in the vertical direction, and a swing movement mechanism 221e that turns (swings) the top ring 221 about the support shaft 221b as the center of turn. The rotational movement mechanism 221c, the vertical movement mechanism 221d, and the swing movement mechanism 221e function as a substrate movement mechanism that moves the relative position between the polishing pad 2200 and the surface to be polished of the wafer W.

The polishing fluid supply unit 222 includes a polishing fluid supply nozzle 222a that supplies polishing fluid to the polishing surface of the polishing pad 2200, a swing movement mechanism 222c that is supported by a support shaft 222b and turns the polishing fluid supply nozzle 222a about the support shaft 222b as the center of turn, a flow rate adjustment unit 222d that adjusts the flow rate of the polishing fluid, and a temperature control mechanism 222e that adjusts the temperature of the polishing fluid. The polishing fluid may be a polishing liquid (slurry) or pure water, and may further include a chemical solution or be a polishing liquid to which a dispersant has been added.

The dresser 223 includes a rotational movement mechanism 223c that is supported by a dresser shaft 223a that is movable in the vertical direction to rotationally drive the dresser 223 about its axis, a vertical movement mechanism 223d that moves the dresser 223 in the vertical direction, and a swing movement mechanism 223e that turns the dresser 223 about a support shaft 223b as the center of turn.

The atomizer 224 includes a swing movement mechanism 224b that is supported by a support shaft 224a to turn the atomizer 224 about the support shaft 224a as the center of turn, and a flow rate adjustment unit 224c that adjusts the flow rate of the pad cleaning fluid. The pad cleaning fluid may be a mixed fluid of liquid (for example, pure water) and gas (for example, nitrogen gas), or a liquid (for example, pure water) alone.

The wafer W is held by suction on the lower surface of the top ring 221 and moved to a predetermined polishing position on the polishing table 220, and then is polished by being pressed by the top ring 221 against the polishing surface of the polishing pad 2200 to which polishing fluid has been supplied from the polishing fluid supply nozzle 222a.

In FIG. 3, the specific configurations of the rotational movement mechanisms 220b, 221c, and 223c, the vertical movement mechanisms 221d and 223d, and the swing movement mechanisms 221e, 222c, 223e, and 224b, which respectively function as movable parts, are omitted. However, for example, they may be configured by appropriately combining AC devices such as servo motors, power transmission mechanisms such as linear quides, ball screws, gears, belts, couplings, and bearings, output devices such as fluid pressure cylinders and valves, and input devices such as linear sensors, encoder sensors, limit sensors, and torque sensors. In FIG. 3, the specific configurations of the flow rate adjustment units 222d and 224c are omitted, but they may be configured by appropriately combining output devices for fluid regulation such as pumps, valves, and regulators, and input devices such as flow sensors, pressure sensors, liquid level Sensors, temperature sensors, fluid concentration sensors, fluid property sensors, and fluid particle sensors, for example. In FIG. 3, the specific configurations of the temperature control mechanisms 220c and 222e are omitted, but they may be configured by appropriately combining AC devices such as contact-type or non-contact-type heaters, and input devices such as temperature sensors and current sensors, for example.

### Substrate Transport Unit

As shown in FIG. 2, the substrate transport unit 23 includes first and second linear transporters 230A and 230B that are horizontally movable along the arrangement direction (longitudinal direction of the housing 20) of the first to fourth polishing units 22A to 22D, a swing transporter 231 disposed between the first and second linear transporters 230A and 230B, a lifter 232 disposed on the side of the load/unload unit 21, and a temporary placement table 233 for the wafer W disposed on the side of the finishing unit 24.

The first linear transporter 230A is a mechanism that is disposed adjacent to the first and second polishing units 22A and 22B to transport the wafer W among four transport positions (defined as first to fourth transport positions TP1 to TP4 in order from the load/unload unit 21 side). The second transport position TP2 is a position for delivering the wafer W to and from the first polishing unit 22A, and the third transport position TP3 is a position for delivering the wafer W to and from the second polishing unit 22B.

The second linear transporter 230B is a mechanism that is disposed adjacent to the third and fourth polishing units 22C and 22D to transport the wafer W among three transport positions (defined as fifth to seventh transport positions TP5 to TP7 in order from the load/unload unit 21 side), The sixth transport position TP6 is a position for delivering the wafer W to and from the third polishing unit 22C, and the seventh transport position TP7 is a position for delivering the wafer W to and from the fourth polishing unit 22D.

The swing transporter 231 includes a hand that is disposed adjacent to the fourth and fifth transport positions TP4 and TP5 and is movable between the fourth and fifth transport positions TP4 and TP5. The swing transporter 231 is a mechanism for delivering the wafer W between the first and second linear transporters 230A and 230B, and for temporarily placing the wafer W on the temporary placement table 233. The lifter 232 is a mechanism that is disposed adjacent to the first transport position TP1 to deliver the wafer W to and from the transport robot 211 of the load/unload unit 21. During the delivery of the wafer W, a shutter (not shown) provided in the first partition wall 200A is opened and closed.

In FIG. 2, the specific configurations of the first and second linear transporters 230A and 230B, the swing transporter 231, and the lifter 232, which respectively function as movable parts, are omitted. However, for example, they may be configured by appropriately combining AC devices such as servo motors, power transmission mechanisms such as linear guides, ball screws, gears, belts, couplings, and bearings, output devices such as fluid pressure cylinders and valves, and input devices such as linear sensors, encoder sensors, limit sensors, and torque sensors.

### Finishing Unit

As shown in FIG. 2, the finishing unit 24 includes first and second roll sponge cleaning units 24A and 24B, arranged in two stages vertically as a substrate cleaning device using a roll sponge 2400, first and second pen sponge cleaning units 24C and 24D, arranged in two stages vertically as a substrate cleaning device using a pen sponge 2401, first and second drying units 24E and 24F, arranged in two stages vertically as a substrate drying device for drying the wafer W after cleaning, and first and second transport units 24G and 24H for transporting the wafer W. It is to be noted that the number and arrangement of the roll sponge cleaning units 24A and 24B, the pen sponge cleaning units 24C and 24D, the drying units 24E and 24F, and the transport units 24G and 24H are not limited to the example shown in FIG. 2 and may be appropriately modified.

The units 24A to 24H of the finishing unit 24 are arranged in a partitioned state along the first and second linear transporters 230A and 230B, in the order, for example, of the first and second roll sponge cleaning units 24A and 24B, the first transport unit 24G, the first and second pen sponge cleaning units 24C and 24D, the second transport unit 24H, and the first and second drying units 24E and 24F (in order from the side farther from the load/unload unit 21). The finishing unit 24 sequentially performs a primary cleaning process by either of the first and second roll sponge cleaning units 24A and 24B, a secondary cleaning process by either of the first and second pen sponge cleaning units 24C and 24D, and a drying process by either of the first and second drying units 24E and 24F, on the wafer W after polishing processing. Note that the processing order by the respective units 24A to 24H of the finishing unit 24 may be appropriately changed, and part of the processing may be omitted. For example, the cleaning process by the roll sponge cleaning units 24A and 24B may be omitted, and the cleaning process may start from the pen sponge cleaning units 24C and 24D. Furthermore, the finishing unit 24 may be configured to perform buff cleaning by including a buff cleaning unit (not shown) in place of either the roll sponge cleaning units 24A or 24B and the pen sponge cleaning units 24C and 24D, or in addition to the roll sponge cleaning units 24A and 24B and the pen sponge cleaning units 24C and 24D. Moreover, in the present embodiment, the units 24A to 24H of the finishing unit 24 are configured to hold the wafer W in a horizontal posture (horizontal holding), but they may also be configured to hold the wafer W in a vertical or inclined posture.

The roll sponge 2400 and the pen sponge 2401 are made of synthetic resin such as PVA or nylon and have a porous structure. The roll sponge 2400 and the pen sponge 2401 function as cleaning tools for scrubbing the wafer W and are replaceably attached to the first and second roll sponge cleaning units 24A and 24B and to the first and second pen sponge cleaning units 24C and 24D, respectively,

The first transport unit 24G includes a first transport robot 246A capable of moving in the vertical direction. The first transport robot 246A is configured to be accessible to the temporary placement table 233 of the substrate transport unit 23, the first and second roll sponge cleaning units 24A and 24B, and the first and second pen sponge cleaning units 24C and 24D, and is provided with upper and lower two-stage hands for delivering wafers W between them. For example, the lower hand is used when delivering an uncleaned wafer W, and the upper hand is used when delivering a cleaned wafer W. During the delivery of wafers W to and from the temporary placement table 233, a shutter (not shown) provided in the second partition wall 200B is opened and closed.

The second transport unit 24H includes a second transport robot 246B capable of moving in the vertical direction. The second transport robot 246B is configured to be accessible to the first and second pen sponge cleaning units 24C and 24D and the first and second drying units 24E and 24F and is provided with a hand for delivering the wafer W among them,

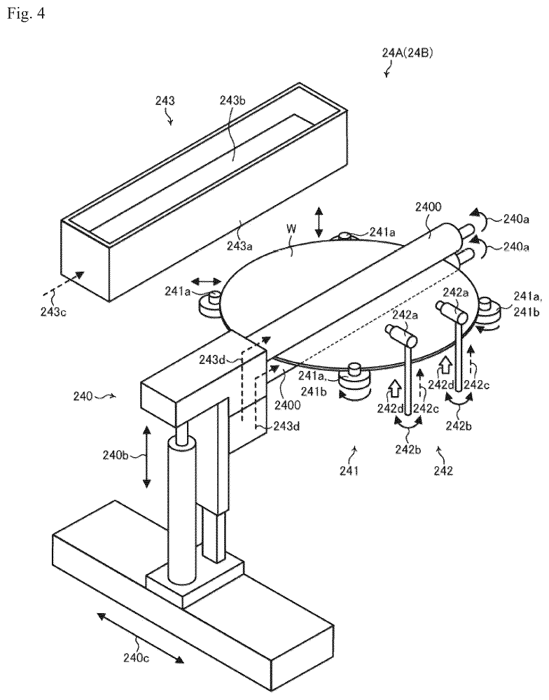

FIG. 4 is a perspective view showing an example of the first and second roll sponge cleaning units 24A and 24B. The basic configurations and functions of the first and second roll sponge cleaning units 24A and 24B are the same, In the example shown in FIG. 4, the first and second roll sponge cleaning units 24A and 24B include a pair of roll sponges 2400 arranged vertically so as to sandwich the cleaning target surface (the front and back surfaces) of the wafer W.

Each of the first and second roll sponge cleaning units 24A and 24B includes a substrate holding unit 241 for holding the wafer W, a cleaning fluid supply unit 242 for supplying cleaning fluid to the wafer W, a substrate cleaning unit (processing member support unit) 240 for rotatably supporting the roll sponge 2400 and bringing the roll sponge 2400 into contact with the wafer W to clean the wafer W, and a cleaning tool cleaning unit 243 for cleaning (self-cleaning) the roll sponge 2400 using a cleaning tool cleaning fluid.

The substrate holding unit 241 includes a substrate holding mechanism 241a that holds the wafer Wat a plurality of points on its side edge and a substrate rotating mechanism 241b that rotates the wafer W about a third rotation axis perpendicular to the cleaning target surface of the wafer W. In the example shown in FIG. 4, the substrate holding mechanism 241a is composed of four rollers, at least one of which is configured to be movable to hold or release the side edge of the wafer W. In the example shown in FIG. 4, the substrate rotating mechanism 241b is composed of two drive rollers, which also function as the substrate holding mechanism 241a that holds the wafer W. The substrate holding unit 241 may also be composed of a substrate holding mechanism 241a formed by a plurality of rollers and a substrate rotating mechanism 241b formed by at least one drive roller. Further, the substrate holding mechanism 241a may be composed of a chuck instead of rollers.

The cleaning fluid supply unit 242 includes a cleaning fluid supply nozzle 242a that supplies cleaning fluid to the cleaning target surface of the wafer W, a swing movement mechanism 242b that turns the cleaning fluid supply nozzle 242a, a flow rate regulator 242c that adjusts the flow rate and pressure of the cleaning fluid, and a temperature control mechanism 242d that adjusts the temperature of the cleaning fluid. The cleaning fluid may be either pure water (rinsing liquid) or a chemical solution. As shown in FIG. 4, the cleaning fluid supply nozzle 242a may be provided with separate nozzles for pure water and for chemical solution. Moreover, the cleaning fluid may be a liquid, a two-fluid mixture of liquid and gas, or a fluid containing solids such as dry ice.

The substrate cleaning unit 240 includes a cleaning tool rotating mechanism 240a that rotates the roll sponge 2400 around a first rotation axis parallel to the cleaning target surface of the wafer W, a vertical movement mechanism 240b that moves at least one of the pair of roll sponges 2400 in the vertical direction to change their height and the distance between them, and a linear movement mechanism 240c that moves the pair of roll sponges 2400 in the horizontal direction. The vertical movement mechanism 240b and the linear movement mechanism 240c function as a cleaning tool movement mechanism that moves the relative position of the roll sponge 2400 and the cleaning target surface of the wafer W.

The cleaning tool cleaning unit 243 includes a cleaning tool cleaning tank 2438 that is arranged in a position where it does not interfere with the wafer W and is capable of storing and discharging cleaning tool cleaning fluid, a cleaning tool cleaning plate 243b housed in the cleaning tool cleaning tank 243a where the roll sponge 2400 is pressed against, a flow rate regulator 243c that adjusts the flow rate and pressure of the cleaning tool cleaning fluid supplied to the cleaning tool cleaning tank 243a, and a flow rate regulator 243d that adjusts the flow rate and pressure of the cleaning tool cleaning fluid circulating through the interior of the roll sponge 2400 and discharged from its outer surface. The cleaning tool cleaning fluid may be pure water (rinse fluid) or a chemical solution.

In the primary cleaning process performed by the first and second roll sponge cleaning units 24A and 24B, the wafer W is rotated by the substrate rotating mechanism 241b while being held by the substrate holding mechanism 241a. Then, cleaning fluid is supplied from the cleaning fluid supply nozzle 242a to the cleaning target surface of the wafer W, and the roll sponge 2400, rotated around its axis by the cleaning tool rotating mechanism 240a, contacts the cleaning target surface of the wafer W, thereby cleaning the wafer w. Thereafter, the substrate cleaning unit 240 moves the roll sponge 2400 to the cleaning tool cleaning tank 243a, where the roll sponge 2400 is cleaned, for example, by rotating it, pressing it against the cleaning tool cleaning plate 243b, or supplying cleaning tool cleaning fluid to the roll sponge 2400 via the flow rate regulator 243d.

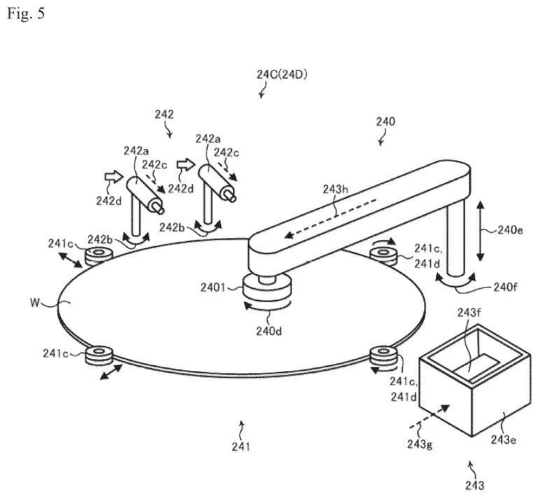

FIG. 5 is a perspective view showing an example of the first and second pen sponge cleaning units 24C and 24D. The basic configurations and functions of the first and second pen sponge cleaning units 24C and 24D are the same.

Each of the first and second pen sponge cleaning units 24C and 24D includes a substrate holding unit 241 for holding the wafer W, a cleaning fluid supply unit 242 for supplying cleaning fluid to the wafer W, a substrate cleaning unit (processing member support unit) 240 for rotatably supporting the pen sponge 2401 and bringing it into contact with the wafer W to clean the wafer W, and a cleaning tool cleaning unit 243 for cleaning (self-cleaning) the pen sponge 2401 using the cleaning tool cleaning fluid. Below, details of the pen sponge cleaning units 240 and 24D will be explained, mainly focusing on the differences from the roll sponge cleaning units 24A and 24B.

The substrate holding unit 241 includes a substrate holding mechanism 241c that holds the side edge of the wafer W at several points and a substrate rotating mechanism 241d that rotates the wafer W around a third rotation axis perpendicular to the cleaning target surface of the wafer W. In the example shown in FIG. 5, the substrate holding mechanism 241c is composed of four rollers, at least one of which is configured to be movable to hold or release the side edge of the wafer W. In the example shown in FIG. 5, the substrate rotating mechanism 241d is composed of two drive rollers, and the drive rollers constituting the substrate rotating mechanism 241b also functions as part of the substrate holding mechanism 241a that holds the wafer W. The substrate holding unit 241 may also be composed of a substrate holding mechanism 241c formed by a plurality of rollers and a substrate rotating mechanism 241d formed by at least one drive roller. Additionally, the substrate holding mechanism 241c may be composed of a chuck instead of rollers.

The cleaning fluid supply unit 242 is configured similarly to that shown in FIG. 4, and includes a cleaning fluid supply nozzle 242a, a swing movement mechanism 242b, a flow rate regulator 242c, and a temperature control mechanism 242d.

The substrate cleaning unit 240 includes a cleaning tool rotating mechanism 240d that rotates the pen sponge 2401 around a second rotation axis perpendicular to the cleaning target surface of the wafer W, a vertical movement mechanism 240e that moves the pen sponge 2401 in the vertical direction, and a swing movement mechanism 240f that turns the pen sponge 2401 in the horizontal direction. The vertical movement mechanism 240e and the swing movement mechanism 240f function as a cleaning tool movement mechanism that moves the relative position of the pen sponge 2401 and the cleaning target surface of the wafer W.

The cleaning tool cleaning unit 243 includes a cleaning tool cleaning tank 243e that is arranged in a position where it does not interfere with the wafer W and is capable of storing and discharging cleaning tool cleaning fluid, a cleaning tool cleaning plate 243f housed in the cleaning tool cleaning tank 243e where the pen sponge 2401 is pressed against, a flow rate regulator 243g that adjusts the flow rate and pressure of the cleaning tool cleaning fluid supplied to the cleaning tool cleaning tank 243e, and a flow rate regulator 243h that adjusts the flow rate and pressure of the cleaning tool cleaning fluid circulating through the interior of the pen sponge 2401 and discharged from its outer surface.

In the secondary cleaning process performed by the first and second pen sponge cleaning units 24C and 24D, the wafer W is rotated by the substrate rotating mechanism 241d while being held by the substrate holding mechanism 241c. Then, cleaning fluid is supplied from the cleaning fluid supply nozzle 242a to the cleaning target surface of the wafer W, and the pen sponge 2401, rotated around its axis by the cleaning tool rotating mechanism 240d, contacts the cleaning target surface of the wafer W, thereby cleaning the wafer W. Thereafter, the substrate cleaning unit 240 moves the pen sponge 2401 to the cleaning tool cleaning tank 243e, where the pen sponge 2401 is cleaned, for example, by rotating it, pressing it against the cleaning tool cleaning plate 243f, or supplying cleaning tool cleaning fluid to the pen sponge 2401 via the flow rate regulator 243h.

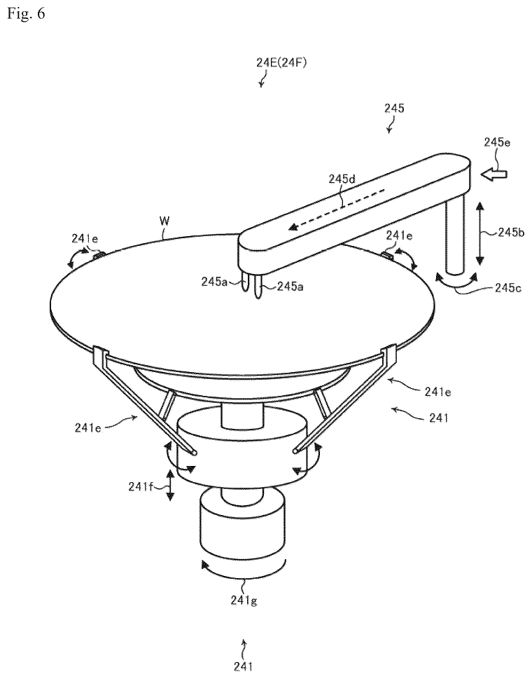

FIG. 6 is a perspective view showing an example of the first and second drying units 24E and 24F, The basic configurations and functions of the first and second drying units 24E and 24F are the same.

Each of the first and second drying units 24E and 24F includes a substrate holding unit 241 that holds the wafer W and a drying fluid supply unit 245 that supplies drying fluid to the wafer W.

The substrate holding unit 241 includes a substrate holding mechanism 241e that holds a plurality of points along the side edge of the wafer W and a substrate rotating mechanism 241g that rotates the wafer W around a third rotation axis perpendicular to the cleaning target surface of the wafer W. The substrate holding mechanism 241e is composed of a chuck in which one end is installed to rotate around a horizontal axis with respect to a vertical movement mechanism 241f that moves in the vertical direction and the other end can move toward and away from the peripheral edge of the wafer W. The substrate holding mechanism 241e constitutes an umbrella mechanism in which the gripping portion moves toward and away from the wafer W in conjunction with the vertical movement of the vertical movement mechanism 241f. The substrate holding mechanism 241e may also be composed of rollers instead of a chuck.

The drying fluid supply unit 245 includes a drying fluid supply nozzle 245a that supplies drying fluid to the cleaning target surface of the wafer W, a vertical movement mechanism 245b that moves the drying fluid supply nozzle 245a in the vertical direction, a swing movement mechanism 245c that turns the drying fluid supply nozzle 245a in the horizontal direction, a flow rate regulator 245d that adjusts the flow and pressure of the drying fluid, and a temperature control mechanism 245e that adjusts the temperature of the drying fluid. The vertical movement mechanism 245b and the swing movement mechanism 245c function as a drying fluid supply nozzle movement mechanism that moves the relative position between the drying fluid supply nozzle 245a and the cleaning target surface of the wafer W. The drying fluid may be, for example, IPA vapor and pure water (rinse liquid), and as shown in FIG. 6, the drying fluid supply nozzle 245a may be provided with Separate nozzles for IPA vapor and pure water. Moreover, the drying fluid may be a liquid, a two-fluid mixture of liquid and gas, or a fluid containing solids such as dry ice.

During the drying process by the first and second drying units 24E and 24F, the wafer W is held by the substrate holding mechanism 241e and rotated by the substrate rotating mechanism 241g. Then, while the drying fluid is supplied from the drying fluid supply nozzle 245a to the cleaning target surface of the wafer W, the drying fluid supply nozzle 245a is moved towards the side edge (radial outer side) of the wafer W. After that, the wafer W is dried by high-speed rotation performed by the substrate rotating mechanism 241g.

In FIGS. 4 to 6, the specific configurations of movable parts such as the substrate holding mechanisms 241a, 241c, 241e, the substrate rotating mechanisms 241b, 241d, 241g, the vertical movement mechanisms 240b, 240e, 241f, 245b, linear movement mechanisms 240c, swing movement mechanisms 240f, 242b, 245c, the cleaning tool rotating mechanisms 240a, 240d, and others are omitted. However, for example, they may be configured by appropriately combining AC devices such as servo motors, power transmission mechanisms such as linear quides, ball screws, gears, belts, couplings, and bearings, output devices such as fluid pressure cylinders and valves, and input devices such as linear sensors, encoder sensors, limit sensors, and torque sensors. In FIGS. 4 to 6, the specific configurations of the flow rate regulators 243c, 243d, 243g, 243h, and 245d are omitted, but they may be configured by appropriately combining output devices for fluid regulation such as pumps, valves, and regulators, and input devices such as flow sensors, pressure sensors, liquid level sensors, temperature sensors, fluid concentration sensors, fluid property sensors, and fluid particle sensors, for example. In FIGS. 4 to 6, the specific configurations of the temperature control mechanisms 242d and 245e are omitted, but they may be configured by appropriately combining AC devices such as contact or non-contact heaters, along with input devices such as temperature sensors and current sensors, for example.

### Control Unit

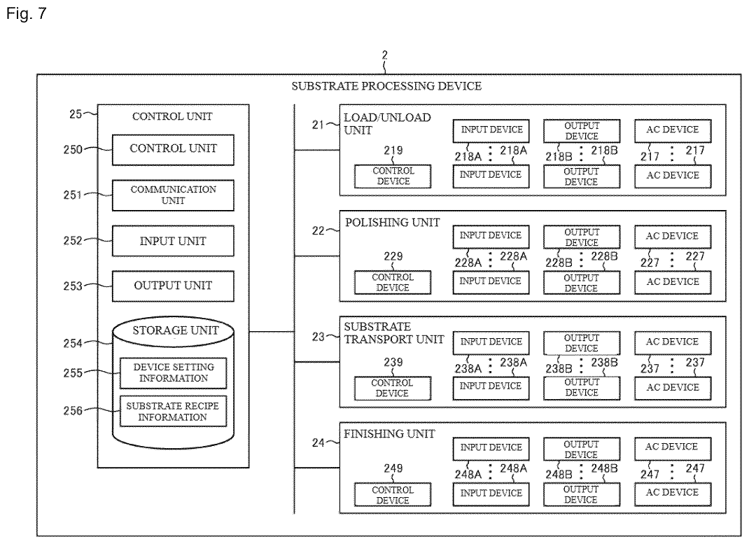

FIG. 7 is a block diagram showing an example of the substrate processing device 2. The control unit 25 is electrically connected to the units 21 to 24 and functions as the control unit that centrally controls each of the units 21 to 24. The following description will focus on the control system (AC devices, input devices, output devices, and control devices) for the polishing unit 22 and the finishing unit 24 as examples, but since other units 21 and 23 have the same basic structure and functions, their descriptions will be omitted.

The polishing unit 22 includes a plurality of AC devices 227 and output devices 228B that are to be controlled and are arranged in each component (for example, polishing table 220, top ring 221, polishing fluid supply unit 222, dresser 223, atomizer 224, and the like) of the polishing unit 22, a plurality of input devices 228A that detect data (detection values) necessary for controlling each component, and a control device 229 that controls the AC devices 227 and the output devices 228B based on the detection values from each input device 228A.

The finishing unit 24 includes a plurality of AC devices 247 and output devices 248B that are to be controlled and arranged in each component (for example, first and second roll sponge cleaning units 24A and 24B, first and second pen sponge cleaning units 24C and 24D, first and second drying units 24E and 24F, first and second transport units 24G and 24H, and the like) of the finishing unit 24, a plurality of input devices 248A that detect data (detection values) necessary for controlling each component, and a control device 249 that controls the operation of the AC devices 247 and the output devices 248B based on the detection values from each input device 248A.

The control unit 25 includes a control unit 250, a communication unit 251, an input unit 252, an output unit 253, and a storage unit 254. The control unit 25 may be composed of, for example, a general-purpose or dedicated computer (see FIG. 8 below).

The communication unit 251 is connected to the network 7 and functions as a communication interface for transmitting and receiving various types of data. The input unit 252 accepts various input operations, while the output unit 253 functions as a user interface by outputting various types of information through the display screen, signal tower lighting, and buzzer sounds.

The storage unit 254 stores various programs (operating system (OS), application programs, web browsers, and the like) and data (device setting information 255, substrate recipe information 256, and the like) used in the operation of the substrate processing device 2. The device setting information 255 and substrate recipe information 256 are data that can be edited by the user through the display screen.

The control unit 250 acquires detection values from the plurality of input devices 218A, 228A, 238A, and 248A (hereinafter referred to as the “input device group”) through the plurality of control devices 219, 229, 239, and 249 (hereinafter referred to as the “control device group”), and operates the plurality of AC devices 217, 227, 237, and 247 (hereinafter referred to as the “AC device group”) and the plurality of output devices 218B, 228B, 238B, and 248B (hereinafter referred to as the “output device group”) in cooperation to perform a series of substrate processing. The control unit 250 also performs interlock control based on interlock information 111 received from the safety support device 5 when it receives the interlock information 111.

### Hardware Configuration of Each Device

FIG. 8 shows an example of the hardware configuration of the computer 900. The control unit 25 of the substrate processing device 2, the database device 3, the machine learning device 4, the safety support device 5, and the user terminal device 6 are each configured by a general-purpose or dedicated computer 900.

As shown in FIG. 8, the computer 900 has, as its main components, a bus 910, processor 912, memory 914, input device 916, output device 917, display device 918, storage device 920, communication I/F (interface) unit 922, external device I/F unit 924, I/O (input/output) device I/F unit 926, and media input/output unit 928. The above-described components may be omitted as appropriate depending on the use of the computer 900.

The processor 912 is configured of one or more arithmetic processing units (CPU (Central Processing Unit), MPU (Micro-Processing Unit), DSP (Digital Signal Processor), GPU (Graphics Processing Unit), NPU (Neural Processing Unit), and the like) and functions as the control unit that manages the entire computer 900. The memory 914 stores various types of data and programs 930 and is composed of, for example, volatile memory (DRAM, SRAM, and the like) functioning as main memory, and non-volatile memory (ROM), flash memory, and the like.

The input device 916 is composed of, for example, a keyboard, mouse, numeric keypad, electronic pen, and the like, and functions as the input unit. The output device 917 is composed of, for example, audio (sound) output devices, vibration devices, and the like, and functions as the output unit. The display device 918 is composed of, for example, a liquid crystal display, organic EL display, electronic paper, projector, and the like, and functions as the output unit. The input device 916 and the display device 918 may be integrally configured, such as in the form of a touch panel display. The storage device 920 is composed of, for example, an HDD, SSD, and the like, and functions as the storage unit. The storage device 920 stores various types of data necessary for executing the operating system and programs 930.

The communication I/F unit 922 is connected to a network 940 (which may be the same as the network 7 in FIG. 1) such as the Internet or an intranet via wired or wireless means, and functions as a communication unit that transmits and receives data to and from other computers according to a predetermined communication standard. The external device I/F unit 924 is connected to an external device 950 such as a camera, a printer, a scanner, a reader/writer, and the like, via wired or wireless means, and functions as a communication unit that transmits and receives data to and from the external device 950 according to a predetermined communication standard. The I/O device I/F unit 926 is connected to an I/O device 960 such as various sensors and actuators, and functions as a communication unit that transmits and receives various signals and data, such as, for example, detection signals from sensors and control signals to actuators, to and from the I/O device 960. The media input/output unit 928 is composed of, for example, drive devices such as DVD drives, CD drives, memory card slots, USB connectors, and functions to read and write data to media (non-volatile storage media) 970 such as DVDs, CDs, memory cards, and USB memory.

In the computer 900 having the above configuration, the processor 912 calls up the program 930 stored in the storage device 920 into the memory 914, executes it, and controls each part of the computer 900 via the bus 910. The program 930 may be stored in the memory 914 instead of the storage device 920. The program 930 may be recorded in the medium 970 in an installable file format or an executable file format, and provided to the computer 900 via the media input/output unit 928. The program 930 may be provided to the computer 900 by downloading it via the network 940 through the communication I/F unit 922. Furthermore, the various functions realized by the processor 912 executing the programs 930 may also be realized by hardware such as an FPGA (Field-Programmable Gate Array) or an ASIC (Application-Specific Integrated Circuit), for example.

The computer 900 may be configured as a desktop computer or portable computer, for example, and is an electronic device of any form. The computer 900 may be a client-type computer, a server-type computer, a cloud-type computer, or an embedded-type computer such as a control panel, controller (including microcontrollers, programmable logic controllers, sequencers), and the like. The computer 900 may also be applied to devices other than devices 2 to 6.

### Machine Learning Device 4

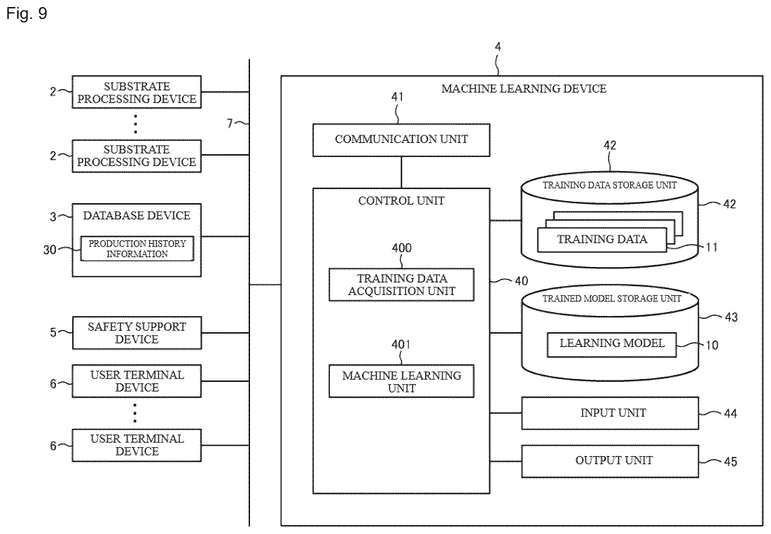

FIG. 9 is a block diagram showing an example of the machine learning device 4. The machine learning device 4 includes a control unit 40, a communication unit 41, a training data storage unit 42, a trained model storage unit 43, an input unit 44, and an output unit 45.

The control unit 40 functions as a training data acquisition unit 400 and a machine learning unit 401. The communication unit 41 is connected to external devices (such as the substrate processing device 2, the database device 3, the safety support device 5, the user terminal device 6, a three-dimensional model device (not shown), and the like) via a network 7 and functions as a communication interface for transmitting and receiving various types of data. The input unit 44 accepts various input operations, while the output unit 45 functions as a user interface by outputting various types of information via a display screen or audio.

The training data acquisition unit 400 acquires training data 11, which consists of image data 110 as input data and interlock information 111 as output data. The training data acquisition unit 400 may acquire the training data 11 by cooperating with an external device connected via the communication unit 41 and the network 7, or may acquire the training data 11 by accepting input operations via the input unit 44 and the output unit 45. The training data 11 is used as teacher data (training data), validation data, and test data in supervised learning. The interlock information 111 is data used as a correct answer label in Supervised learning.

The training data storage unit 42 is a database that stores a plurality of sets of training data 11 acquired by the training data acquisition unit 400. The specific structure of the database that constitutes the training data storage unit 42 can be appropriately designed.

The machine learning unit 401 performs machine learning using the plurality of sets of training data 11 stored in the training data storage unit 42. That is, the machine learning unit 401 generates a trained learning model 10 by inputting a plurality of sets of training data 11 into the learning model 10 and training the learning model 10 to learn the correlation between the image data 110 and the interlock information 111 included in the training data 11.

The trained model storage unit 43 is a database that stores the trained learning model 10 (specifically, the adjusted weight parameter group) generated by the machine learning unit 401. The trained learning model 10 stored in the trained model storage unit 43 is provided to an actual system (for example, the safety support device 5) via the network 7 or a recording medium. In FIG. 9, the training data storage unit 42 and the trained model storage unit 43 are shown as separate storage units, but they may be configured as a single storage unit.

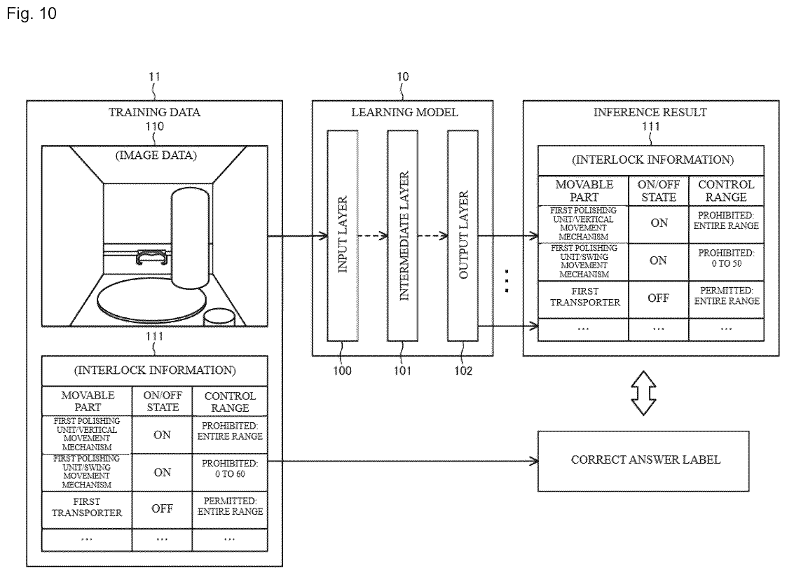

FIG. 10 shows an example of the learning model 10 and the training data 11. The training data 11 used for machine learning of the learning model 10 consists of image data 110 and interlock information 111.

The image data 110 constituting the training data 11 is captured by an image capturing unit 63 arranged in front of the operator U when the operator U wears the user terminal device 6. The image data 110, for example, is captured when the operator U performs a task on the substrate processing device 2 with at least part of their body within the movable range of the movable part and each part of the substrate processing device 2 captured under various capturing conditions, such as different capturing positions, capturing angles, and capturing ranges.

The interlock information 111 constituting the training data 11 includes at least one of the interlock on/off state and the interlock control range, as an interlock state. The interlock on/off state indicates the permission or prohibition of movement of the movable part, where movement permission is the state in which movement of the movable part is allowed, and movement prohibition is the state in which movement of the movable part is prohibited. The interlock control range shows the permitted or prohibited movement range of the movable part relative to the movable range in the axis coordinate system (position and angle) of the movable part. The movement permission range is the range where movement of the movable part is permitted, and the movement prohibition range is the range where movement of the movable part is prohibited.

The interlock information 111 may include interlock information 111 for only a single specific movable part, Or, as shown in FIG. 10, may include interlock information 111 for a plurality of movable parts. When the interlock information 111 includes interlock information 111 for a plurality of movable parts, it is sufficient that the information includes, for each movable part, at least one of the interlock on/off state and the interlock control range.

The training data acquisition unit 400 acquires the image data 110 captured by the image capturing unit 63 under various capturing conditions, for example, by allowing a test subject wearing the user terminal device 6 to take a position and posture similar to those of an actual operator U when performing a task on the substrate processing device 2 using the substrate processing device 2 for actual production or the substrate processing device 2 for testing. Moreover, the training data acquisition unit 400 acquires the interlock information 111 of the movable parts for the position and posture when the image data 110 was captured. The interlock information 111 may be input by the test subject via the user terminal device 6 or via the input unit 44 and output unit 45.

The training data acquisition unit 400 acquires, as the image data 110, virtual space data assumed to be captured by the image capturing unit 63 when it is assumed that the operator U exists at a specific position in a virtual space where the three-dimensional shape of each part of the substrate processing device 2 is reproduced, for example, using, for example, a three-dimensional model provided by a three-dimensional model device. Moreover, the training data acquisition unit 400 acquires the interlock information 111 of the movable part based on whether there is a high risk that the movable part collides with the operator U when it is assumed that the movable part moves within its movable range.

The learning model 10 adopts, for example, a neural network structure, comprising an input layer 100, an intermediate layer 101, and an output layer 102. Synapses (not shown) that connect each neuron are laid between each layer, and each synapse is associated with a weight. A group of weight parameters consisting of the weights of each synapse is adjusted through machine learning.

The input layer 100 has a number of neurons corresponding to the number of pixels in the image data 110 as input data, and the pixel values of each pixel are input to the respective neurons. The output layer 102 has a number of neurons corresponding to the interlock information 111 as output data, and the prediction results (inference results) for the interlock information 111 corresponding to the image data 110 are output as output data.

The number of learning models 10 stored in the trained model storage unit 43 is not limited to one. For example, a plurality of learning models with different conditions may be stored, such as variations in machine learning methods, differences in the structure of the substrate processing device 2, differences in the specifications of the image capturing unit 63 (for example, resolution or type of image sensor), and variations in the types of data included in the interlock information 111. In such cases, the training data storage unit 42 may store a plurality of types of training data having a data structure corresponding to the plurality of learning models with different conditions.

### Machine Learning Method

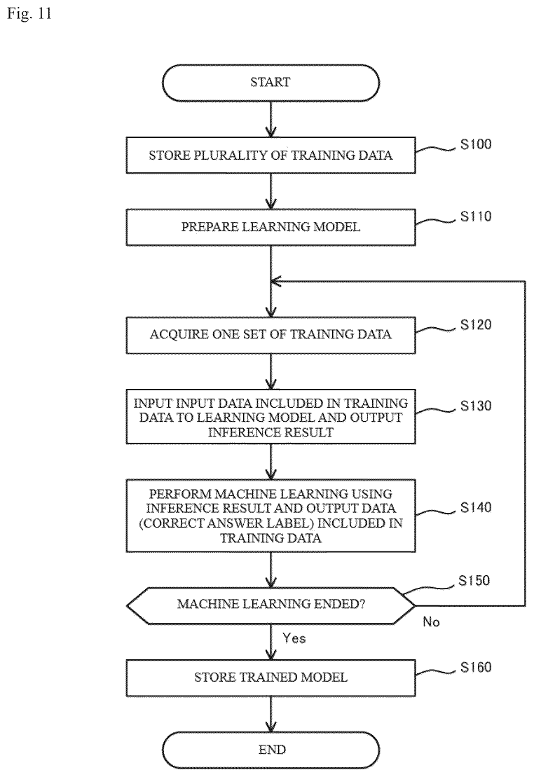

FIG. 11 is a flowchart showing an example of the machine learning method performed by the machine learning device 4.

First, in step S100, the training data acquisition unit 400 acquires a desired number of pieces of training data 11 as a preparation for starting the machine learning process, and stores the acquired training data 11 in the training data storage unit 42. The number of pieces of training data 11 to be prepared here may be set in consideration of the inference accuracy required for the learning model 10 to be finally obtained.

Next, in step S110, the machine learning unit 401 prepares a learning model 10 before training in order to start machine learning. The learning model 10 before training prepared here is composed of a neural network model, and the weights of each synapse are set to initial values.

Next, in step S120, the machine learning unit 401 acquires one set of training data 11, for example, randomly from a plurality of sets of training data 11 stored in the training data storage unit 42.

Next, in step S130, the machine learning unit 401 inputs the input data (image data 110) included in the one set of training data 11 into the input layer 100 of the prepared learning model 10 before (or during) training. As a result, output data (interlock information 111) is output from the output layer 102 of the learning model 10 as the inference result, but the output data is generated by the learning model 10 before (or during) training. Therefore, in the state before (or during) training, the output data output as the inference result indicates information different from the correct answer label (interlock information 111) included in the training data 11.

Next, in step S140, the machine learning unit 401 compares the correct answer label included in the one set of training data 11 obtained in step S120 with the output data output from the output layer 102 as the inference result in step S130, and performs a process (backpropagation) of adjusting the weight of each synapse, thereby performing machine learning. As a result, the machine learning unit 401 causes the learning model 10 to learn the correlation between the input data and output data.

Next, in step S150, the machine learning unit 401 checks whether predetermined learning end conditions have been satisfied. For example, this is determined based on an evaluation value of an error function based on the correct answer label included in the training data 11 and the output data output as an inference result, or based on the remaining number of pieces of untrained training data 11 stored in the training data storage unit 42.

In step S150, if the machine learning unit 401 determines that the learning end conditions have not been satisfied and learning is to be continued (No in step S150), the process returns to step S120, and the processes of steps S120 to S140 are repeated a plurality of times on the learning model 10 during training using the untrained training data 11. On the other hand, if the machine learning unit 401 determines that the learning end conditions are satisfied and learning is to be ended (Yes in step S150), the process proceeds to step S160.

In step S160, the machine learning unit 401 stores the trained learning model 10 (adjusted weight parameter group) generated by adjusting the weights associated with each synapse in the trained model storage unit 43, and ends the series of machine learning methods shown in FIG. 11. In this machine learning method, step S100 corresponds to a training data storage process, steps S110 to S150 correspond to a machine learning process, and step S160 corresponds to a trained model storage process.

As described above, according to the machine learning device 4 and the machine learning method according to the present embodiment, it is possible to provide the learning model 10 capable of predicting (inferring) the interlock information 111 indicating the interlock state of the movable part from the image data 110 captured by the image capturing unit 63, which is arranged in front of the operator U when the operator U wears the user terminal device 6.

### Safety Support Device 5

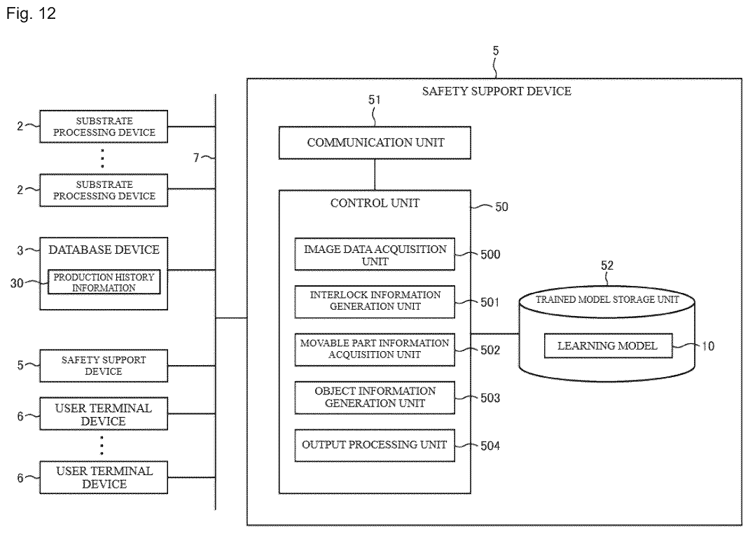

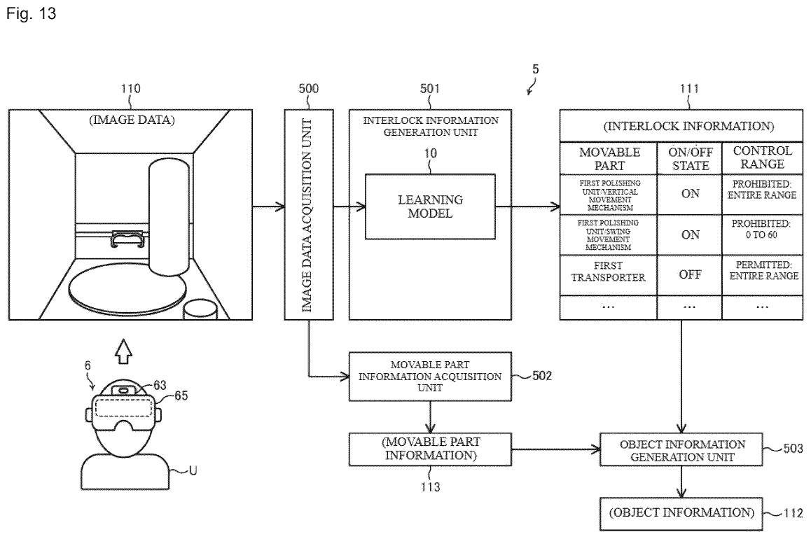

FIG. 12 is a block diagram showing an example of the safety support device 5. FIG. 13 is a functional diagram showing an example of the safety support device 5. The safety support device 5 includes a control unit 50, a communication unit 51, and a storage unit 52.

The control unit 50 functions as an image data acquisition unit 500, an interlock information generation unit 501, a movable part information acquisition unit 502, an object information generation unit 503, and an output processing unit 504. The communication unit 51 is connected via the network 7 to external devices (for example, the substrate processing device 2, database device 3, machine learning device 4, user terminal device 6, and the like) and serves as a communication interface for transmitting and receiving various types of data. The storage unit 52 stores various programs (such as operating systems and user terminal programs), data (learning models 10), and the like used in the operation of the safety support device 5.

The image data acquisition unit 500 acquires image data 110 captured by the image capturing unit 63 arranged in front of the operator U when the operator U wears the user terminal device 6. In the present embodiment, the image data acquisition unit 500 acquires (receives) the image data 110 via the communication unit 51 and network 7 from the user terminal device 6.

The interlock information generation unit 501 generates interlock information 111 based on the image data 110 acquired by the image data acquisition unit 500. In the present embodiment, the interlock information generation unit 501 generates the interlock information 111 for the acquired image data 110 by inputting the image data 110 acquired by the image data acquisition unit 500 into the learning model 10, which has been trained with the correspondence between the image data 110 and the interlock information 111.

The storage unit 52 stores the trained learning model 10 used by the interlock information generation unit 501. The number of learning models 10 stored in the storage unit 52 is not limited to one. For example, a plurality of trained models with different conditions may be stored, such as variations in machine learning methods, differences in the structure of the substrate processing device 2, variations in the specifications of the image capturing unit 63 (for example, resolution of type of image sensor), and variations in the types of data included in the interlock information 111. These models may be selectively or concurrently utilized. The storage unit 52 may be replaced with a storage unit of an external computer (for example, a server-type or cloud-type computer), in which case the interlock information generation unit 501 and the interlock information generation unit 501 would access this external computer.

The movable part information acquisition unit 502 acquires movable part information 113 indicating the position of the movable parts existing around the operator U based on the image data 110 obtained by the image data acquisition unit 500. For example, the movable part information acquisition unit 502 determines whether the feature points of the movable parts are included within the angle of view when the image capturing unit 63 captures the real space. If the feature points of the movable parts are detected, the movable part information acquisition unit 502 acquires the movable part information 113 based on the position of the feature points. The feature points may be based on, for example, the external shape or color of the movable part, or on characters or two-dimensional codes on stickers affixed to the movable part. In cases where design diagram data of the each part of the substrate processing device 2 is stored in the storage unit 52, and the feature points of the movable part in the design diagram data are detected within the capturing range when the real space was captured by the image capturing unit 63, the movable part information acquisition unit 502 may refer to the design diagram data to acquire the spatial position information of the movable part based on those feature points.

The object information generation unit 503 generates object information 112 for superimposing the interlock information 111 on the movable parts existing around the operator U when the user terminal device 6 is worn by the operator U, based on the interlock information 111 generated by the interlock information generation unit 501 and the movable part information 113 acquired by the movable part information acquisition unit 502.

The output processing unit 504 performs output processing for outputting the interlock information 111 generated by the interlock information generation unit 501 or the object information 112 generated by the object information generation unit 503. For example, the output processing unit 504 transmits the interlock information 111 to the substrate processing device 2 or the user terminal device 6, whereby interlock control based on the interlock information 111 is performed in the substrate processing device 2, and a display screen or sound based on the interlock information 111 is output from the user terminal device 6. Furthermore, the output processing unit 504 transmits the object information 112 to the user terminal device 6, whereby a display screen based on the object information 112 is output.

### User Terminal Device 6

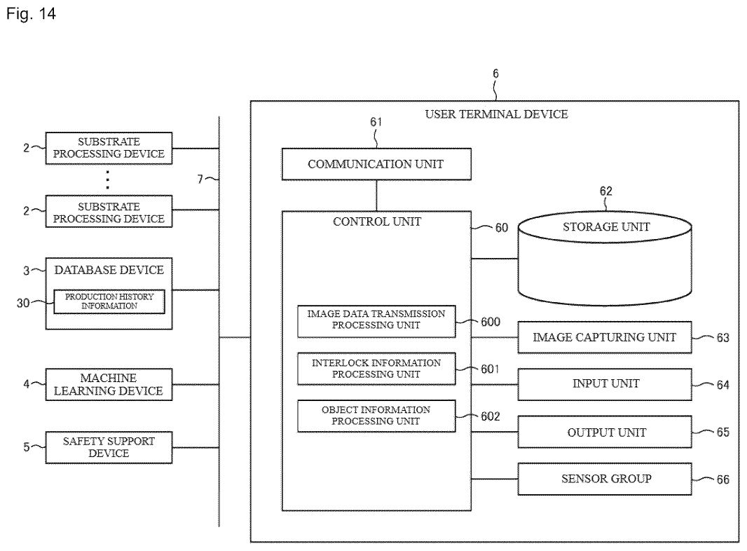

FIG. 14 is a block diagram showing an example of the user terminal device 6. The user terminal device 6 includes a control unit 60, a communication unit 61, a storage unit 62, an image capturing unit 63, an input unit 64, an output unit 65, and a sensor group 66.

The control unit 60 functions as an image data transmission processing unit 600, an interlock information processing unit 601, and an object information processing unit 602. The communication unit 61 is connected to external devices (for example, substrate processing device 2, database device 3, machine learning device 4, safety support device 5, and the like) through the network 7, and functions as a communication interface for transmitting and receiving various types of data. The storage unit 62 stores various programs (such as operating systems and user terminal programs) data, and the like used for the operation of the user terminal device 6. The image capturing unit 63 captures the real space and generates image data 110. The input unit 64 accepts various input operations, and the output unit 65 functions as a user interface by outputting various types of information through a display screen or sound. The sensor group 66 detects the acceleration, angular velocity, and posture of the device itself.

The image data transmission processing unit 600 transmits the image data 110, captured by the image capturing unit 63 at a predetermined capture cycle, to the safety support device 5 through the communication unit 61 and network 7 as needed.

The interlock information processing unit 601 receives the interlock information 111 from the safety support device 5 in response to the image data 110 transmitted from the safety support device 5, and notifies the operator U of the interlock information 111 through sound or the display screen by, for example, the output unit 65.

The object information processing unit 602 receives the object information 112 from the safety support device 5 in response to the image data 110 transmitted from the safety support device 5, and superimposes the interlock information 111 onto the movable parts existing around the operator U via the output unit 65 based on the object information 112, thereby notifying the operator U of the interlock information 111.

### Safety Support Method

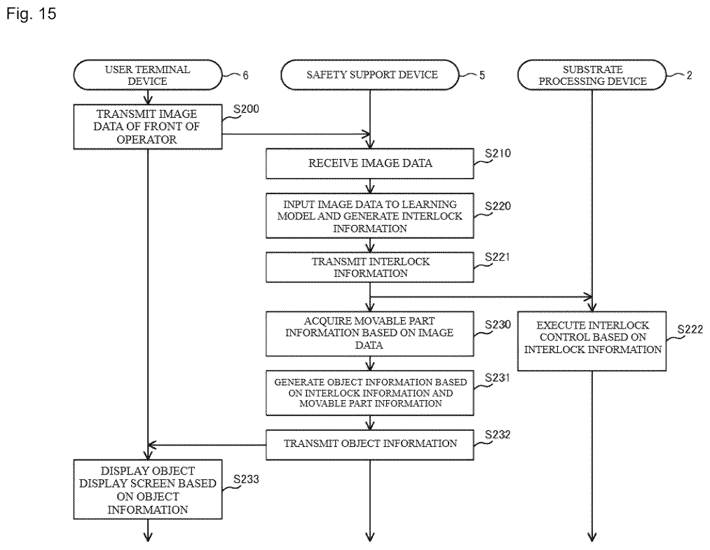

FIG. 15 is a flowchart showing an example of the Safety support method performed by the substrate processing device 2, safety support device 5, and user terminal device 6. In the following, an example of the operation of the substrate processing device 2, the safety support device 5, and the user terminal device 6 will be described when the operator U wearing the user terminal device 6 opens the cover attached to the first polishing unit 22A of the substrate processing device 2 and performs an adjustment operation on the substrate processing device 2 to adjust the second transport position TP2 for delivering the wafer W between the top ring 221 in the first polishing unit 22A and the first linear transporter 230A as the operation on the substrate processing device 2. In the flowchart shown in FIG. 15, the user terminal device 6 starts capturing images using the image capturing unit 63 when it receives an input operation from the operator U instructing to start an adjustment operation, and the flowchart is executed repeatedly each time the capturing period of the image capturing unit 63 has elapsed.

First, at step S200, the image capturing unit 63 of the user terminal device 6 captures the real space in front of the operator U performing the adjustment operation to generate image data 110. Then, the image data transmission processing unit 600 transmits the image data 110 captured by the image capturing unit 63 to the safety support device 5.

Next, in step S210, the image data acquisition unit 500 of the safety support device 5 receives the image data 110 transmitted in step S200.

Next, in step S220, the interlock information generation unit 501 generates interlock information 111 for the image data 110 based on the output data output by inputting the image data 110 acquired in step S210 into the learning model 10 as input data. In step S221, the output processing unit 504 transmits the interlock information 111 to the substrate processing device 2 as the output processing for outputting the interlock information 111 generated in step S220.

Next, in step S222, the control unit 25 of the substrate processing device 2 performs interlock control based on the interlock information 111 upon receiving the interlock information 111 transmitted in step S221. In step S221, the output processing unit 504 may also transmit the interlock information 111 to the user terminal device 6, in which case, the interlock information processing unit 601 of the user terminal device 6 may notify the operator U of the interlock information 111 via sound or a display screen.

Next, in step S230, the movable part information acquisition unit 502 acquires movable part information 113 indicating the position of the movable parts existing around the operator U based on the image data 110 obtained in step S210.

Next, in step S231, the object information generation unit 503 generates object information 112 for superimposing the interlock information 111 on the movable parts existing around the operator U, based on the interlock information 111 generated in step S220 and the movable part information 113 acquired in step S230. In step S232, the output processing unit 504 transmits the object information 112 to the user terminal device 6 as the output processing for outputting the object information 112 generated in step S231.

Next, in step S233, the object information processing unit 602 of the user terminal device 6 displays a virtual object indicating the interlock information 111 for the movable parts in the real space on the output unit 65 of the user terminal device 6 based on the object information 112 upon receiving the object information 112 transmitted in step S232.

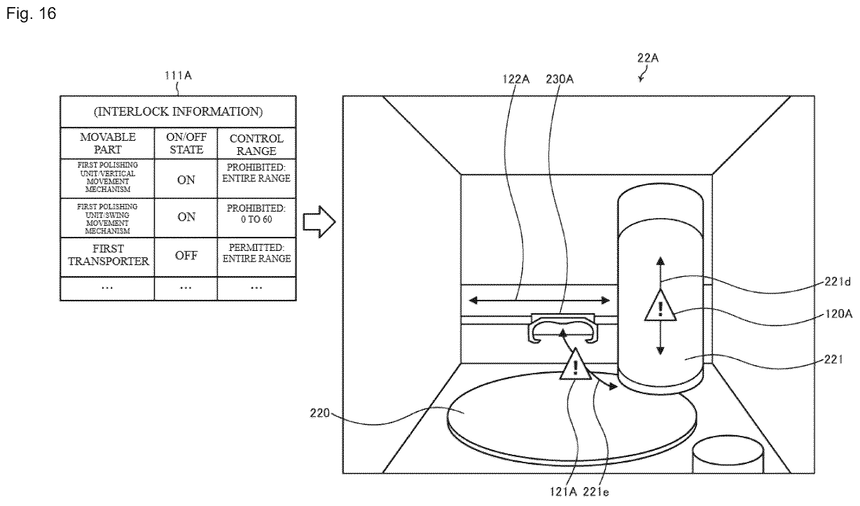

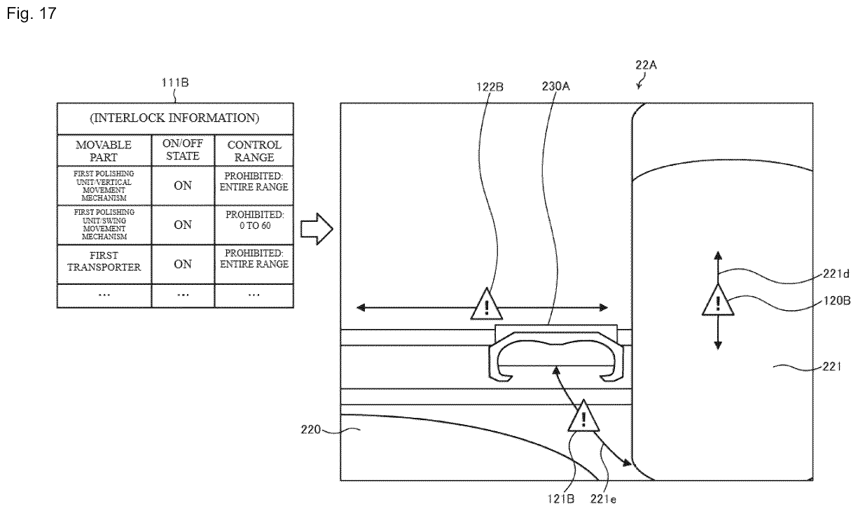

FIG. 16 shows the first example where interlock information 111A is superimposed on the movable parts in the real space. FIG. 17 shows the second example where interlock information 111B is superimposed on the movable parts in the real space. Hereinafter, for the sake of simplification of explanation, it will be described assuming that the angle of view of the image data 110 and the field of view of the operator U coincide with each other, However, the angle of view of the image data 110 and the field of view of the operator U do not necessarily have to coincide, and either one may be wider than the other.

FIG. 16 illustrates a case in which interlock information 111A, generated based on image data 110 captured by the image capturing unit 63 in a state where the operator U is standing in front of the cover of the first polishing unit 22A and the operator can reach the top ring 221 of the first polishing unit 22A, is displayed as virtual objects 120A to 122A.

The virtual objects 120A and 121A indicate that, as interlock information 111A for the top ring 221 of the first polishing unit 22A captured in the image data 110, the interlock for the vertical movement mechanism 221d is ON (movement prohibited), with the entire range set as a prohibited movement range, and the interlock for the swing movement mechanism 221e is ON (movement prohibited), with the range of 0 to 60 set as a prohibited movement range.

The virtual object 122A indicates that, as interlock information 111A for the first linear transporter 230A captured in the image data 110, the interlock for the first linear transporter 230A is OFF (movement permitted), with the entire range set as a permitted movement range.

In accordance with the display of the virtual objects 120A to 122A, interlock control is performed by the substrate processing device 2 in step S222, as shown in FIG. 16, based on the interlock information 111A generated from the image data 110. Specifically, as interlock control for the top ring 221 of the first polishing unit 22A captured in the image data 110, the movement of the vertical movement mechanism 221d is restricted across the entire range, and the movement of the swing movement mechanism 221e is restricted within the range of 0 to 60, similarly to the virtual objects 120A and 121A. In addition, as interlock control for the first linear transporter 230A captured in the image data 110, the movement of the first linear transporter 230A is permitted across the entire range, similarly to the virtual object 122A. That is, when the operator U is standing in front of the cover of the first polishing unit 22A and their hand can reach the top ring 221 of the first polishing unit 22A, there is no risk of collision between the operator U and the first linear transporter 230A, and thus the movement of the first linear transporter 230A is permitted.

FIG. 17 illustrates a case in which interlock information 111B, generated based on the image data 110 captured by the image capturing unit 63 in a state where the operator U has inserted their upper body into the interior of the first polishing unit 22A and their hand can reach the first linear transporter 230A, is displayed as virtual objects 120B to 122B.

The virtual objects 120B and 121B indicate that, as interlock information 111B for the top ring 221 of the first polishing unit 22A captured in the image data 110, the interlock for the vertical movement mechanism 221d is ON (movement prohibited), with the entire range set as a prohibited movement range, and the interlock for the swing movement mechanism 221e is ON (movement prohibited), with the range of 0 to 60 set as a prohibited movement range. The virtual object 122B indicates that, as interlock information 111B for the first linear transporter 230A captured in the image data 110, the interlock for the first linear transporter 230A is ON (movement prohibited), with the entire range set as a prohibited movement range.

In accordance with the display of the virtual objects 120B to 122B, interlock control is performed by the substrate processing device 2 in step S222, as shown in FIG. 17, based on the interlock information 111B generated from the image data 110. Specifically, as interlock control for the top ring 221 of the first polishing unit 22A captured in the image data 110, the movement of the vertical movement mechanism 221d is restricted across the entire range, and the movement of the swing movement mechanism 221e is restricted within the range of 0 to 60, similarly to the virtual objects 120B and 121B. In addition, as interlock control for the first linear transporter 230A captured in the image data 110, the movement of the first linear transporter 230A is prohibited across the entire range, similarly to the virtual object 122B. That is, when the operator U has inserted their upper body into the interior of the first polishing unit 22A and their hand can reach the first linear transporter 230A, there is a risk of collision between the operator U and the first linear transporter 230A, and thus the movement of the first linear transporter 230A is prohibited.

It is to be noted that in FIGS. 16 and 17, the interlock information 111A and 111B has been described as including the interlock states for the movable parts, that is, the vertical movement mechanism 221d and the swing movement mechanism 221e of the top ring 221, and the first linear transporter 230A. However, the interlock information may additionally include the interlock states for other movable parts. As examples of such other movable parts, movable parts captured in the image data 110, that is, those within the angle of view of the image capturing unit 63 of the user terminal device 6 worn by the operator U, may be used, or alternatively, movable parts estimated to exist around the operator U may also be included.

As described above, while interlock control is performed by the substrate processing device 2, the operator U can recognize the interlock states of the movable parts by viewing the virtual objects 120A to 122A and 120B to 122B displayed on the output unit 65. Then, as the position or orientation of the body of the operator U changes and accordingly the capturing conditions of the image data 110 change, the processes for generating the interlock information 111 and the object information 112 are repeatedly executed. Thus, the operator U can safely perform operations on the substrate processing device 2. It should be noted that, in the above-described safety support method, step S210 corresponds to an image data acquisition step, step S220 corresponds to an interlock information generation step, step S230 corresponds to a movable part information acquisition step, and Step S231 corresponds to an object information generation step.

According to the safety support device 5 and safety Support method of the present embodiment, when the operator U wearing the user terminal device 6 performs tasks with at least part of their body within the movable range of a movable part of the substrate processing device 2, the interlock information 111 of the movable part is generated based on the image data 110 captured by the image capturing unit 63, which is disposed in front of the operator U. Thus, the interlock of the movable part can be controlled based on the positional relationship between the operator U and the movable part. Accordingly, it is possible to improve the work efficiency of the operator U while appropriately ensuring the safety of the operator U. In addition, according to the safety support device 5 and the safety support method of the present embodiment, since the interlock information 111 is superimposed and displayed on the movable parts in the real space, the operator U can recognize the interlock states of the movable parts.

### Other Embodiments

The present invention is not limited to the above-described embodiment, and various modifications can be made without departing from the spirit of the present invention. All of these modifications are included in the technical concept of the present invention.

In the above-described embodiment, the database device 3, the machine learning device 4, the safety support device 5, and the user terminal device 6 are described as being configured as separate devices, but these four devices may be configured as a single device, or any two or three of these devices may be configured as a single device. Furthermore, at least one of the machine learning device 4 and the safety support device 5 may be incorporated into the control unit 25 of the substrate processing device 2 or the user terminal device 6. For example, the learning model 10 may be stored in the storage unit 62 of the user terminal device 6, and the control unit 60 of the user terminal device 6 may function as the image data acquisition unit 500, the interlock information generation unit 501, the movable part information acquisition unit 502, and the object information generation unit 503.

In the above-described embodiment, the substrate processing device 2 has been described as including the units 21 to 24. However, the substrate processing device 2 may be any processing device that performs at least one of polishing, cleaning, and drying, for example, as substrate processing. As the polishing process, physical mechanical polishing may be used instead of chemical mechanical polishing.

In the above-described embodiment, the machine learning device 4, the safety support device 5, and the user terminal device 6 have been described as being applied to the substrate processing device 2 that performs substrate processing. However, they may be applied to any processing device that performs predetermined processing by moving a movable part having a predetermined movable range. The processing device may be a closed-type device, similar to the substrate processing device 2, in which a housing 20 is provided with a cover or door and a movable part is arranged within the enclosed space inside the cover or door. Alternatively, it may be an open-type device in which the movable part is arranged in an open space, such as indoors or outdoors, without a cover or door.

In the above-described embodiment, a neural network is used as a learning model for realizing machine learning by the machine learning unit 401, but other machine learning models may be used. Examples of other machine learning models include tree-based models such as decision trees and regression trees, ensemble learning methods such as bagging and boosting, neural network-based models (including deep learning) such as recurrent neural networks, convolutional neural networks and LSTM, clustering-based models such as hierarchical clustering, non-hierarchical clustering, k-nearest neighbors and k-means clustering, multivariate analyses such as principal component analysis, factor analysis, and logistic regression, and support vector machines.

In the above-described embodiment, the interlock information generation unit 501 of the safety support device 5 has been described as generating interlock information 111 based on the image data 110 acquired by the image data acquisition unit 500 using a trained learning model 10. However, other methods may also be employed. As an alternative method, for example, a rule-based approach using image processing may be adopted. In this case, the interlock information generation unit 501 may acquire operator information indicating the position of the operator U by performing image processing on the image data 110 acquired by the image data acquisition unit 500, and generate interlock information 111 for the image data 110 based on the acquired operator information. The position of the operator U may be, for example, an absolute position based on an arbitrary origin within the housing 20 of the substrate processing device 2, or a relative position from the movable part based on the position of the movable part. Then, the interlock information generation unit 501 may determine whether there is a high risk of collision between the operator U and the movable part based on the positional relationship (distance or height) between the operator U and the movable part and generate the interlock information 111 based on the result of this determination. At this time, the interlock information generation unit 501 may generate the interlock information 111 by taking into account the position of the movable part at the time of the determination. The position of the movable part may be acquired, for example, by the movable part information acquisition unit 502 through image processing of the image data 110, or by receiving a report R from the control unit 25 of the substrate processing device 2 via the communication unit 51 and the network 7.

In the above-described embodiment, the case where the safety support device 5 operates according to the flowchart shown in FIG. 15 has been described. However, the execution order of each step may be appropriately modified, and some steps may be omitted. For example, steps S230 to S232 may be omitted.

### Machine Learning Program and Safety Support Program

The present invention may also be provided in the form of a program (machine learning program) that causes the computer 900 to function as each part of the machine learning device 4, or a program (machine learning program) that causes the computer 900 to execute each step of the machine learning method. The present invention can also be provided in the form of a program (safety support program) for causing the computer 900 to function as each unit of the safety support device 5 or the user terminal device 6, or a program (safety support program) for causing the computer 900 to execute each step of the safety support method according to the above-described embodiment.

### Inference Device, Inference Method, and Inference Program

The present invention can also be provided in the form of an inference device (inference method or inference program) used to infer interlock information, in addition to the safety support device 5 (safety support method or safety support program) according to the above-described embodiment. In that case, the inference device (inference method or inference program) can include a memory and a processor, and the processor executes a series of processes. The series of processes includes an image data process (image data acquisition step) for acquiring the image data 110, and an inference process (inference step) for inferring interlock information 111 indicating interlock state of the movable part based on the image data when the image data is acquired in the image data acquisition process.

By providing it in the form of an inference device (inference method or inference program), it can be easily applied to various devices compared to implementing a safety support device. It can be naturally understood by those skilled in the art that when the inference device (inference method or inference program) infers interlock information, the inference method implemented by the interlock information generation unit can be applied using a trained learning model generated by the machine learning device and machine learning method according to the above-described embodiment.

### REFERENCE SIGNS LIST

1 Substrate processing system,
2 Substrate processing device,
3 Database device,
4 Machine learning device,
5 Safety support device,
6 User terminal device (operator device),
7 Network,
10 Learning model,
11 Training data,
20 Housing,
21 Load/Unload unit,
22 Polishing unit,
23 Substrate transport unit,
24 Finishing unit,
25 Control unit,
40 Control unit,
41 Communication unit,
42 Training data storage unit,
43 Trained model storage unit,
44 Input unit,
45 Output unit,
50 Control unit,
51 Communication unit,
52 Storage unit,
60 Control unit,
61 Communication unit,
62 Storage unit,
63 Image capturing unit,
64 Input unit,
65 Output unit,
66 Sensor group,
110 Image data,
111 111A, 111B Interlock information,
112 Object information,
113 Movable part information,
120A to 122A, 120B to 122B Virtual objects,
400 Training data acquisition unit,
401 Machine learning unit,
500 Image data acquisition unit,
501 Interlock information generation unit,
502 Movable part information acquisition unit,
503 Object information generation unit,
504 Output processing unit,
600 Image data transmission processing unit,
601 Interlock information processing unit,
602 Object information processing unit,
900 Computer,
U Operator,
W Wafer

1. A safety support device that supports the safety of an operator who performs a predetermined task by placing at least a part of their body into a predetermined movable range with respect to a processing device that performs predetermined processing by moving a movable part having the predetermined movable range, the safety support device comprising:
an image data acquisition unit that acquires image data captured by an image capturing unit disposed in front of the operator when an operator device including the image capturing unit is worn by the operator; and
an interlock information generation unit that generates interlock information indicating an interlock state of the movable part based on the image data acquired by the image data acquisition unit.

2. The safety support device according to claim 1, wherein
the interlock information generation unit acquires operator information indicating a position of the operator by performing image processing on the image data acquired by the image data acquisition unit, and generates the interlock information for the image data based on the acquired operator information.

3. The safety support device according to claim 1, wherein
the interlock information generation unit generates the interlock information for the image data by inputting the image data acquired by the image data acquisition unit into a learning model that has been machine-trained with a correlation between the image data and the interlock information.

4. The safety support device according to claim 1, further comprising:
a movable part information acquisition unit that acquires movable part information indicating a position of the movable part existing around the operator based on the image data acquired by the image data acquisition unit; and
an object information generation unit that generates object information for superimposing the interlock information on the movable part existing around the operator when the operator device is worn by the operator, the operator device further including an output unit which is capable of superimposing the object information on an object in a real space based on the interlock information generated by the interlock information generation unit and the movable part information acquired by the movable part information acquisition unit.

5. The safety support device according to claim 1, wherein
the interlock information includes, as the interlock state, at least one of:
an interlock on/off state indicating permission or prohibition of movement of the movable part; and
an interlock control range indicating a permitted or prohibited movement range of the movable part relative to the movable range.

6. An inference device comprising a memory and a processor, wherein
the processor executes:
an image data acquisition process of acquiring image data captured by an image capturing unit disposed in front of an operator when an operator device including the image capturing unit is worn by the operator who performs a predetermined task by placing at least a part of their body into a predetermined movable range with respect to a processing device that performs predetermined processing by moving a movable part having the predetermined movable range; and
an inference process of inferring interlock information indicating an interlock state of the movable part based on the image data when the image data is acquired in the image data acquisition process.

7. A machine learning device comprising:
a training data storage unit that stores a plurality of sets of training data, each set including image data captured by an image capturing unit disposed in front of an operator when an operator device including the image capturing unit is worn by the operator who performs a predetermined task by placing at least a part of their body into a predetermined movable range with respect to a processing device that performs predetermined processing by moving a movable part having the predetermined movable range and interlock information indicating an interlock state of the movable part;
a machine learning unit that causes a learning model to learn a correlation between the image data and the interlock information by inputting the plurality of sets of training data to the learning model; and
a trained model storage unit that stores the learning model trained with the correlation by the machine learning unit.

8. A safety support method for supporting the safety of an operator who performs a predetermined task by placing at least a part of their body into a predetermined movable range with respect to a processing device that performs predetermined processing by moving a movable part having the predetermined movable range, the safety support method comprising:
an image data acquisition step of acquiring image data captured by an image capturing unit disposed in front of the operator when an operator device including the image capturing unit is worn by the operator; and
an interlock information generation step of generating interlock information indicating an interlock state of the movable part based on the image data acquired in the image data acquisition step.

9. An inference method executed by an inference device comprising a memory and a processor, wherein
the processor executes:
an image data acquisition step of acquiring image data captured by an image capturing unit disposed in front of an operator when an operator device including the image capturing unit is worn by the operator who performs a predetermined task by placing at least a part of their body into a predetermined movable range with respect to a processing device that performs predetermined processing by moving a movable part having the predetermined movable range; and
an inference step of inferring interlock information indicating an interlock state of the movable part based on the image data when the image data is acquired in the image data acquisition step.

10. A machine learning method comprising:
a training data storage step of storing a plurality of sets of training data in a training data storage unit, each set including image data captured by an image capturing unit disposed in front of an operator when an operator device including the image capturing unit is worn by the operator who performs a predetermined task by placing at least a part of their body into a predetermined movable range with respect to a processing device that performs predetermined processing by moving a movable part having the predetermined movable range and interlock information indicating an interlock state of the movable part;
a machine learning step of causing a learning model to learn a correlation between the image data and the interlock information by inputting the plurality of sets of training data to the learning model; and
a trained model storage step of storing in a trained model storage unit the learning model trained with the correlation by the machine learning step.
